(19) United States
(12) Patent Application Publication
(10) Pub. No.: US 2009/0153366 A1
(43) Pub. Date: Jun. 18, 2009

(54) USER INTERFACE APPARATUS AND METHOD USING HEAD GESTURE

(75) Inventors: Sungho Im, Daejeon (KR); Dongmyung Sul, Daejeon (KR); Seunghan Choi, Suwon (KR); Kyunghee Lee, Daejeon (KR); Seungmin Park, Daejeon (KR)

Correspondence Address: AMPACC LAW GROUP, 13024 Beverly Park Road, Suite 205, Mukilteo, WA, 98275, US

(73) Assignee: Electrical and Telecommunications Research Institute, Daejeon (KR)

(21) Appl. No.: 12/263,459

(22) Filed: Nov. 1, 2008

(30) Foreign Application Priority Data
Dec. 17, 2007 (KR) 10-2007-0131964

(51) Int. Cl. H03K 17/94; G06K 9/62

(52) U.S. Cl. 341/20; 382/103

(57) ABSTRACT

Disclosed is a user interface apparatus and method using a head gesture. A user interface apparatus and method according to an embodiment of the invention matches a specific head gesture of a user with a specific command and stores a matched result, receives image data of a head gesture of the user and determines whether the received image data corresponds to the specific command, and provides a determined command to a terminal body. As a result, without being affected by ambient noises and causing noise damages to peoples around a terminal, the utilization of the terminal is not inconvenient to the user even in the case where the user can use only one hand.

### RELATED APPLICATIONS

The present application claims priority to Korean Patent Application Serial Number 10-2007-0131964, filed on Dec. 17, 2007, the entirety of which is hereby incorporated by reference.

### BACKGROUND OF THE INVENTION

1. Field of the Invention

The present invention relates to a user interface apparatus and method using a head gesture, and more particularly, to a user interface apparatus and method that can efficiently execute a portion of a keyboard function and a cursor movement function similar to a mouse function, which are frequently used in a portable terminal, using head gesture recognition and buttons.

This work was supported by the IT R&D program of MIC/IITA [2006-S-038-02, Development of Device-Adaptive Embedded Operating System for Mobile Convergence Computing].

2. Description of the Related Art

A portable terminal has been widely used as a personal portable communication unit and has become one of the necessities of life. In recent years, a mobile communication terminal provides not only a function as a communication unit that simply transmits and receives a speech but also new functions, such as a data communication and a video conversion. As a result, the utilization of the mobile communication terminal is increasing.

In the portable terminal, instead of a keyboard or a mouse that is used as an input device of a general computer, hardware buttons or an electronic pen is mainly used. The hardware buttons are used as shortcut keys or direction keys according to corresponding objects. Since a desired menu item on a touch screen can be directly selected by using the electronic pen, the electronic pen can be used as one of effective input units. In particular, since the electronic pen has a function similar to that of a mouse that is used as a pointing device in a general computer, a user of the general computer can easily use the electronic pen.

The portable terminal is small-sized and has excellent portability, which allows the portable terminal to be easily used without needing to consider where the portable terminal is moved and/or the location. However, there are limitations in using the portable terminal. Different from a general computer (desktop or notebook), the portable terminal requires relatively simple functions rather than various and precise input functions. For this reason, the portable terminal has low performance and low power. Further, the portable terminal has a small-sized keypad or keyboard, which makes it difficult to input letters and figures. The portable terminal has a small-sized screen, which makes it difficult for a user to accurately select a desired menu item on a touch screen.

That is, it is difficult to use a keyboard or mouse in the mobile terminal. Since the mobile terminal requires low power consumption and has a light weight, the mobile terminal cannot have excellent performance and function, and an input process using a keyboard or keypad is inconvenient to a user. When the portable terminal is used, a user needs to hold the portable terminal using one hand. If a touch screen is used, the user generally should use both hands. However, it is difficult for the user to accurately select a desired menu item on a small screen due movements of the hands. Meanwhile, the execution of general application programs or simple Internet searching in the portable terminal can be performed by only limited input functions, such as cursor movement or selection, page movement, and a Tab function. These limited input functions are repeatedly performed.

Meanwhile, for a video phone or an image mail, a camera may be mounted in the portable terminal such that the portable terminal is used as an image input device. The portable terminal is also used to implement a speech recognition interface through a microphone. However, in the image input or speech recognition, a recognition rate and a recognition speed are insufficient in causing the portable terminal to implement the speech recognition or the gesture recognition using the camera because of characteristics of the portable terminal that is not excellent in terms of performance and power. As a result, it is difficult to achieve an efficient operation using simple repetitive input functions provided by the portable terminal.

### SUMMARY OF THE INVENTION

Accordingly, the invention has been made to solve the above-described problems, and it is an object of the invention to provide a user interface apparatus and method using a head gesture that can provide a convenient user interface for a portable terminal in which a minimal amount of calculation is required and a recognition process can be accurately and quickly performed.

According to an aspect of the invention, there is provided a user interface apparatus using a head gesture that provides interfacing to a terminal body to a user. In this case, the apparatus matches a specific head gesture of the user with a specific command and stores a matched result, receives image data of a head gesture of the user and determines whether the received image data corresponds to the specific command, and provides a determined command to the terminal body.

The user interface apparatus according to the aspect of the invention may further include a gesture recognizer that receives image data of the user, separates a face region from the received image data, grasps a feature that is needed to recognize a face and stores the feature, and matches at least one head gesture of the user and a command with each other and stores a matched result.

The gesture recognizer may receive the image data of the head gesture of the user, extract a recognition region from the received image data, and analyze a motion of the user on the basis of the extracted recognition region to recognize the head gesture.

The head gesture may include at least one of a horizontal rotational direction and angle of a user's head, a vertical angle of the user's head, a state and motion of a user's mouth, and a state and motion of user's eyes.

The user interface apparatus according to the aspect of the invention may include a camera that photographs an image of the head gesture of the user; and a monitor that displays a recognized result of the head gesture.

The user interface apparatus according to the aspect of the invention may further include a stream manager that analyzes a recognized result of the head gesture input from the gesture recognizer, determines which kind of command the analyzed head gesture is matched with, and transmits a determined result to the monitor.

The stream manager may transmit the image data of the head gesture of the user input from the camera to the gesture recognizer.

The stream manager may determine which kind of command the head gesture is matched with, and provide a determined result to the terminal body.

According to another aspect of the invention, there is provided a user interface method using a head gesture that provides interfacing to a terminal body to a user. The user interface method includes matching a specific head gesture of the user with a specific command and storing a matched result; receiving image data of a head gesture of the user and determining whether the received image data corresponds to the specific command; and providing the determined command to the terminal body.

According to the aspects of the invention, since terminals mounted with cameras, which are not affected by ambient noises and do not cause noise damages to peoples around the terminals are already commonly used, an additional device does not need to be installed. As a result, the cost can be reduced. Since a user can perform button input with one hand holding the terminal, the user can conveniently utilize the terminal using one hand even in the case where the user can use only one hand.

### BRIEF DESCRIPTION OF THE DRAWINGS

FIG. 1 is a block diagram illustrating the structure of a user interface apparatus using a head gesture according to an embodiment of the invention;

FIG. 2 is a flowchart illustrating the operation of a user interface method in a recognition learning mode for recognition region extraction according to an embodiment of the invention;

FIG. 3 is a diagram illustrating a command learning mode in a user interface method according to a preferred embodiment of the invention; and

FIG. 4 is a flowchart illustrating a head gesture recognition process of a user interface apparatus according to an embodiment of the invention.

### DESCRIPTION OF THE PREFERRED EMBODIMENTS

Hereinafter, the preferred embodiments of the invention will be described with reference to the accompanying drawings.

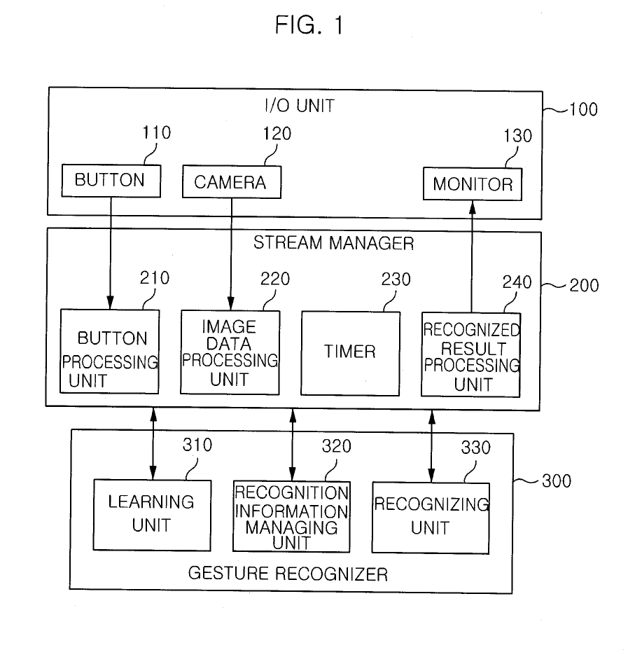

FIG. 1 is a block diagram illustrating the structure of a user interface apparatus using a head gesture according to an embodiment of the invention.

A user interface apparatus according to an embodiment of the invention includes an I/O unit 100, a stream manager 200, and a gesture recognizer 300.

The I/O unit 100 includes a hardware button 110, a camera 120 for image input, and a monitor 130 to display a recognized result.

The stream manager 200 includes a button processing unit 210, an image data processing unit 220, a timer 230, and a recognized result processing unit 240. The button processing unit 210 processes a button input operation, and the image data processing unit 220 collects image data from the camera and transmits the collected image data to the gesture recognizer. The recognized result processing unit 240 analyzes the recognized result to convert the recognized result into a corresponding command, and provides the command to the monitor of the I/O unit 100. The timer 230 sets the recognition time. In this case, the recognized result processing unit 240 transmits the command to a terminal body as well as the monitor, and allows the terminal body to perform an operation or procedure according to the corresponding command.

The gesture recognizer 300 receives image data of a user and separates a face region from the received image data, grasps a feature that is needed to recognize the face and stores the grasped feature, matches at least one head gesture of the user with a command and stores a matched result, receives image data of a head gesture of the user, extracts a recognition region from the received image data to analyze a motion, and recognizes the head gesture.

The gesture recognizer 300 includes a learning unit 310, a recognition information managing unit 320, and a recognizing unit 330. The learning unit 310 previously grasps a face location and processes a command to quickly perform a recognition process. The recognition information managing unit 320 stores information that is obtained through a learning process. The recognizing unit 330 extracts feature information from the image data, and recognizes a head gesture while referring to the recognition information managing unit 320.

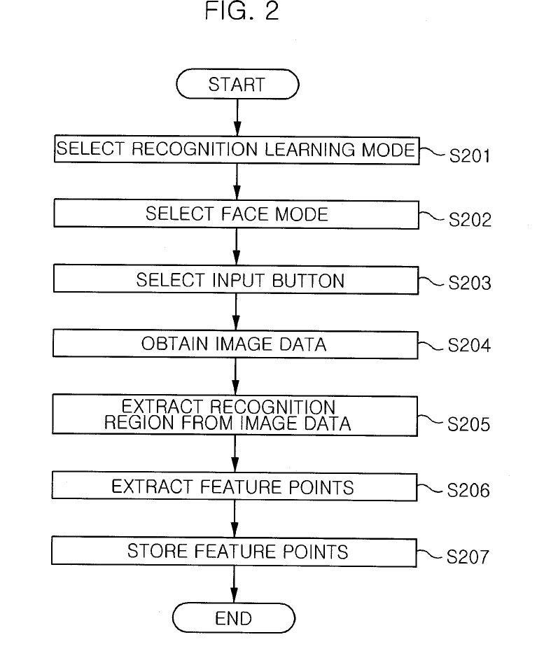

FIG. 2 is a flowchart illustrating the operation of a user interface method in a recognition learning mode for recognition region extraction according to an embodiment of the invention.

The operation shown in FIG. 2 is performed to extract feature points of a user face in order to separate face and mouth regions in the user interface method according to the embodiment of the invention. Specifically, the operation is a process for separating a recognition region from the image data received from the camera and previously extracting information necessary for recognition in the separated recognition region so as to increase a recognition speed.

First, a user selects a recognition learning mode (S201), and then selects a face mode (S202). In this invention, since a user interface is implemented using a head gesture or a face representation, a face mode is selected. After selecting the face mode, a face is photographed by pressing a photographing button installed in a terminal (S203).

If image data of the face is obtained by photographing (S204), a recognition region, that is, a face region is separated from the obtained image data and then extracted (S205). In the extracted recognition region, a shape of the face and a ratio between eyes, a nose, and a mouth are analyzed, and feature points necessary for recognition are extracted (S206), and then stored (S207).

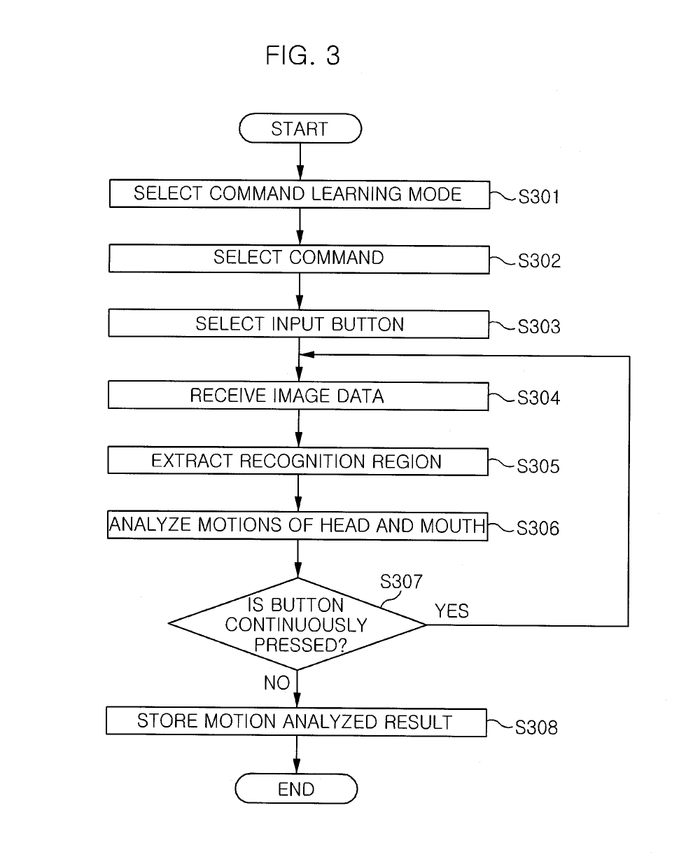

FIG. 3 is a diagram illustrating a command learning mode in a user interface method according to a preferred embodiment of the invention.

In a command learning mode according to the preferred embodiment of the invention shown in FIG. 3, the operation is a procedure to match gestures of a user and commands to be used with each other.

A user selects a command learning mode (S301), and then selects a command (S302). According to the preferred embodiment of the invention, individual commands correspond to gestures, such as movement directions of a head and shapes of a mouth. For example, motions of a head may be represented by movements of a cursor in eight directions, and when a user looks the other way for a predetermined time, it may be represented by fast movements of the cursor. Motions of a mouth (for example, a case where a user opens or closes a mouth) are associated with input of control keys corresponding to a Tab key, an Enter key, and the like, thereby providing a convenient user interface.

As the head gestures according to the embodiment of the invention, a horizontal rotational direction and angle of a user's head, a vertical angle of the user's head, a state and motion of a user's mouth, and a state and motion of user's eyes may be used.

If a command is selected, a user presses a photographing button (S303), and starts to receive image data that is photographed by the camera (S304). The recognition region is separated and extracted from the received image data using information on the recognition region that is extracted in the recognition learning mode (S305), and a motion of the head or mouth in the recognition region is analyzed (S306).

Even after the recognition region analyzing step (S306) is completed, when the photographing button is continuously pressed (Yes of S307), the procedure from Steps S304 to S306 is repeated. When the selection of the photographing button is stopped, the analyzed result until that time is matched with the selected command and a matched result is stored in the recognition information managing unit 320 (S308).

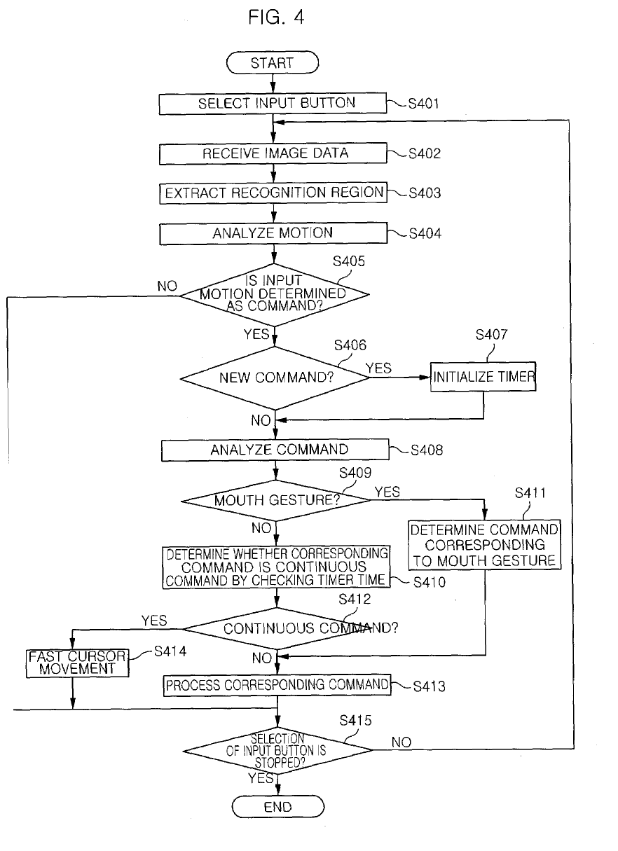

FIG. 4 is a flowchart illustrating a head gesture recognition process of a user interface apparatus according to an embodiment of the invention.

If a user presses an input button (S401), image data is received (S402), a recognition region is extracted from the received image data (S403), and motions of a head and a mouth are analyzed (S404). As an analyzed result, when it is determined that the input motion is an input command (Yes of S405), it is determined whether the corresponding command is a new command (S406). When it is determined that the corresponding command is the new command (Yes of S406), the timer is initialized (S407), and the input command is analyzed (S408). When it is determined that the input command is not the new command (No of S406), the input command is analyzed without setting the timer (S408). At the time of analyzing the input command, that is, at the time of analyzing the gesture, it is determined whether the input motion is a mouth gesture or the motion of the head like when the user looks the other way. In order to determine whether the input motion is the mouth gesture, a current screen and a screen immediately before the current screen are compared with each other to determine whether the location and shape of the mouth are changed to a degree that the location and shape exceed threshold values.

As the analyzed result, when the input motion is not the mouth gesture (No of S409), a timer time is checked to determine whether the input motion is a continuous command (S410). When the same command is continuously input for a predetermined time (Yes of S412), for example, when a user looks the other way for a predetermined time, fast cursor movement is performed (S414). When the input motion is not the continuous command (No of S412), a process according to the corresponding command is performed (S413). For example, the corresponding command is transmitted to the terminal body to allow the terminal body to perform a proper operation according to the received command. Even in the case where the input motion is the mouth gesture (Yes of S409), it is determined which command the mouth gesture corresponds to (S411), and a process according to the corresponding command is performed (S413).

When the selection of the input button is not stopped even after the above-described processes are performed (No of S415), that is, when the input button is continuously pressed, the procedure returns to Step S402, and the processes from the image data receiving step to the performing of the process according to the corresponding command (S413) or the fast cursor movement (S414) are repeated.

As described with reference to the above-described embodiments, the invention is preferably applied to mobile phones that use buttons instead of a keyboard and mount a camera therein, but the invention is not limited thereto. The invention may also be applied to all apparatuses or environments in which a camera is installed, and only some functional buttons are repeatedly used because the utilization of a keyboard is inconvenient to a user.

What is claimed is:

1. A user interface apparatus using a head gesture that provides interfacing to a terminal body for a user,
wherein the apparatus matches a specific head gesture of the user with a specific command and stores a matched result, receives image data of a head gesture of the user, determines whether the received image data corresponds to the specific command, and provides a determined command is provided to the terminal body.

2. The user interface apparatus of claim 1, comprising:
a gesture recognizer that receives image data of the user, separates a face region from the received image data, grasps a feature needed to recognize a face and stores the feature, and matches at least one head gesture of the user and a command with each other and stores a matched result.

3. The user interface apparatus of claim 2,
wherein the gesture recognizer receives the image data of the head gesture of the user, extracts a recognition region from the received image data, and analyzes a motion of the user on the basis of the extracted recognition region to recognize the head gesture.

4. The user interface apparatus of claim 1,
wherein the head gesture includes at least one of a horizontal rotational direction and angle of a user's head, a vertical angle of the user's head, a state and motion of a user's mouth, and a state and motion of user's eyes.

5. The user interface apparatus of claim 1, comprising:
a camera that photographs an image of the head gesture of the user; and
a monitor that displays a recognized result of the head gesture.

6. The user interface apparatus of claim 3, further comprising:
a stream manager that analyzes a recognized result of the head gesture input from the gesture recognizer, determines which kind of command the analyzed head gesture is matched with, and transmits a determined result to a monitor.

7. The user interface apparatus of claim 6,
wherein the stream manager transmits the image data of the head gesture of the user input from the camera to the gesture recognizer.

8. The user interface apparatus of claim 6,
wherein the stream manager determines which kind of command the head gesture is matched with, and provides a determined result to the terminal body.

9. A user interface method using a head gesture that provides interfacing to a terminal body to a user, the user interface method comprising:
matching a specific head gesture of the user with a specific command and storing a matched result;
receiving image data of a head gesture of the user and determining whether the received image data corresponds to the specific command; and
providing the determined command to the terminal body.

10. The user interface method of claim 9,
wherein the matching of the specific head gesture of the user with the specific command and the storing of the matched result includes:
receiving image data of the user, separating a face region from the received image data, grasping a face feature needed to recognize a face, and storing the face feature; and
separating a recognition region from image data input from a camera using the stored face feature, matching each head gesture of the user grasped from the recognition region with a command, and storing a matched result.

11. The user interface method of claim 9,
wherein the determining of whether the received image data corresponds to the specific command includes:
receiving the image data of the head gesture of the user and extracting a recognition region from the received image data; and
analyzing a motion of the extracted recognition region to recognize the head gesture, and determining which command the recognized head gesture corresponds to.

12. The user interface method of claim 9,
wherein the head gesture includes at least one of a horizontal rotational direction and angle of a user's head, a vertical angle of the user's head, a state and motion of a user's mouth, and a state and motion of user's eyes.
